(19) United States
(12) Patent Application Publication
(10) Pub. No.: US 2008/0047694 A1
(43) Pub. Date: Feb. 28, 2008

(54) Heat transfer apparatus and methods

(76) Inventors: Andrew D. Delano, Spokane, WA (US); Christian L. Belady, Richardson, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/511,054

(22) Filed: Aug. 27, 2006

(51) Int. Cl. F28D 15/00; B29C 47/88; H05K 7/20

(52) U.S. Cl. 165/104.33; 361/699; 165/120

(57) ABSTRACT

Liquid heat exchangers and methods for removing heat from a central processing unit. An exemplary heat exchanger comprises a body having an open cavity whose periphery is sealable to the central processing unit from which heat is to be removed, a cooling liquid inlet port coupled through the body to the open cavity, and a liquid outlet port coupled through the body to the open cavity. Cooling liquid is pumped through the cavity when the body is sealed to the central processing unit, thereby contacting the central processing unit and removing heat from the central processing unit. A plurality of heat conducting elements may be provided that extend from an inner surface of the body into the open cavity, at least some of which have a length that is operative to contact the central processing unit. The heat conducting elements allow convective cooling of the central processing unit.

### BACKGROUND

The present invention relates to heat transfer apparatus and methods for use with personal computer systems, and the like.

Heat flux produced by modern microprocessors is approaching values that warrant direct liquid cooling. One technique for use in cooling a microprocessor is to incorporate a liquid heat exchanger as part of a lid that covers the microprocessor. Prior to this, the lid was utilized to spread the heat via conduction, thus reducing the heat flux. However, liquid cooling is not yet widely accepted. Furthermore, in the result of a failure of the liquid cooled system, processor overheating is a serious possibility.

More particularly, silicon microprocessors are often bonded to a high conductivity lid which spreads the heat thus reducing the heat flux (heat flow rate per unit area). The lid also protects the microprocessor (see FIGS. 1 and 2). Historically, microprocessor heat flux has been increasing with each new generation of microprocessor, and this trend continues today. It is expected that the trend of increasing heat flux from microprocessors will continue, and within the next couple of years, the heat flux may reach values which will require direct liquid cooling for maximum performance.

In a typical conventional liquid heat exchanger, the liquid cooled lid contains inlet and exit ports and cooling liquid is pumped over the processor. While this technique provides the advantages of liquid cooling, it does not solve the following two problems.

(1) What happens if the liquid system fails (i.e., a leak, pump failure, etc)? The processor is insulated from the surface of the heat exchanger by a large fluid gap. In the case of fluid loss or pump failure, the heat must conduct through the liquid (relative to metal, and liquid conductivities are extremely small). (2) What happens to customers who are not prepared to incorporate a liquid cooled solution?

It would be desirable to have a solution to the above two problems.

In addition, in typical plate style liquid heat exchangers, a thermal interface material (TIM) is required to reduce the contact resistance between the liquid heat exchanger and the object with which it exchanges heat. The heat flow must pass through both the thermal interface material and the bottom of the liquid heat exchanger (see FIG. 4). Heat flow is driven by a temperature gradient. This contact resistance and the resistance incurred by conducting into the liquid heat exchanger produce an undesirable temperature gradient which may be relatively large at sufficient power levels. Typically, it is desirable to minimize this temperature gradient.

Thus, while the contact resistance can be reduced using a thermal interface material, there is still incurs an undesirable temperature gradient. In addition, the heat must also flow into the liquid heat exchanger since it closed.

It would be desirable to have a solution to the undesirable temperature gradient problem.

### BRIEF DESCRIPTION OF THE DRAWINGS

The various features and advantages of disclosed embodiments may be more readily understood with reference to the following detailed description taken in conjunction with the accompanying drawings, wherein like reference numerals designate like structural elements, and in which:

FIG. 1 illustrates an exemplary CPU without a lid;

FIG. 2 illustrates an exemplary CPU having a lid;

FIG. 3 is a top view of an exemplary consolidated liquid heat exchanger that may be used with the CPU shown in FIGS. 1 and 2;

FIG. 4 illustrates a bottom view of the consolidated liquid heat exchanger shown in FIG. 3;

FIG. 5 illustrates the consolidated liquid heat exchanger used in conjunction with a CPU;

FIG. 6 is a cutaway view of the consolidated liquid heat exchanger shown in FIGS. 3-5;

FIG. 7 illustrates a bottom view of an exemplary dual mode liquid heat exchanger; and

FIGS. 8 and 9 are cutaway views of the exemplary dual mode liquid heat exchanger used in conjunction with a CPU.

### DETAILED DESCRIPTION

Disclosed are thermal heat transfer devices for use with microprocessors, computers, and other similar devices and systems.

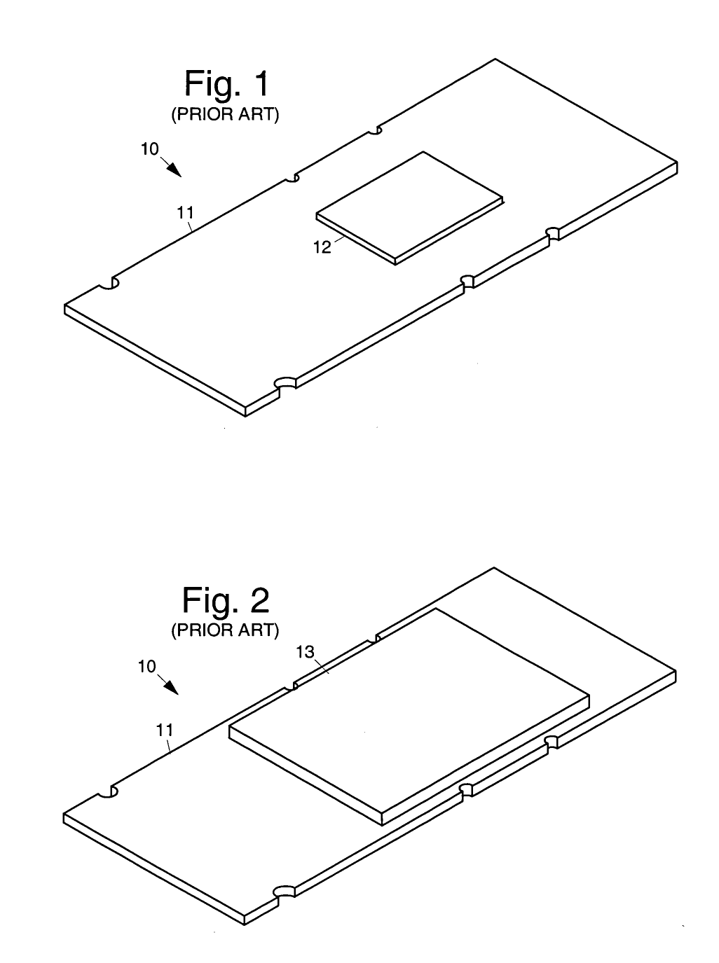

Referring to the drawing figures, FIG. 1 illustrates an exemplary conventional central processing unit (CPU) 10 without a lid. The conventional CPU 10 comprises a microprocessor 12 disposed on a substrate 11. FIG. 2 illustrates an exemplary conventional CPU 10 having a lid 13 covering the microprocessor 12. The thermal heat transfer devices disclosed herein may be employed with microprocessors 12 that are used with or without the lid 13.

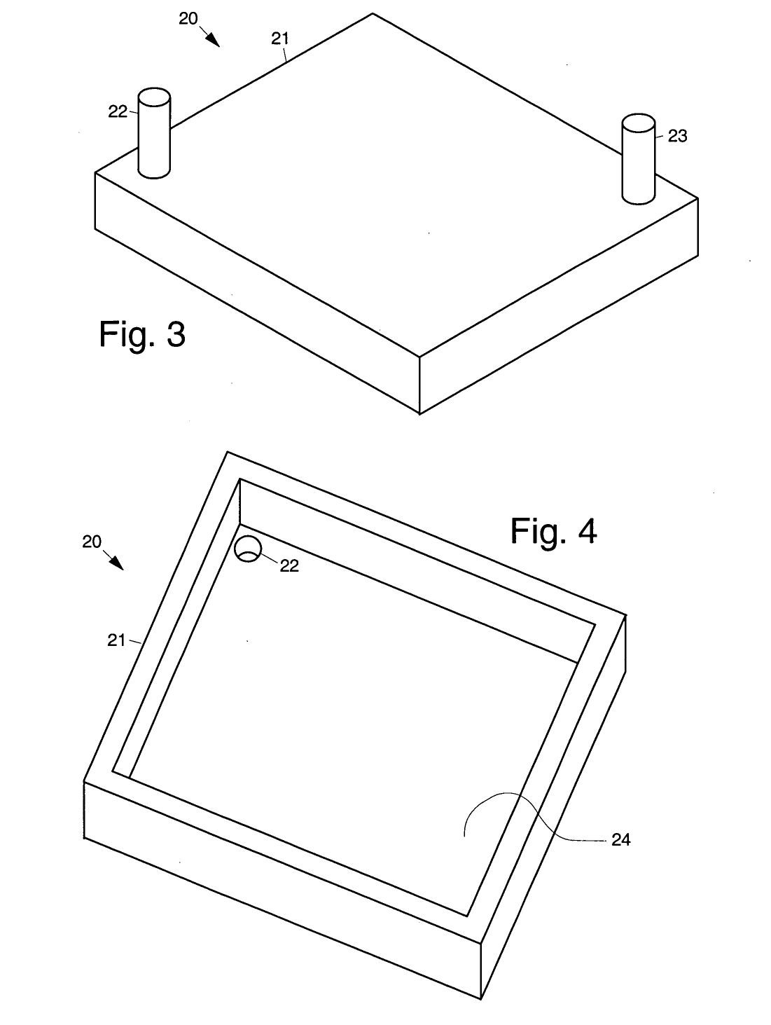

FIG. 3 illustrates a top view of a consolidated, open cavity, liquid heat exchanger 20 that may be used with the microprocessors 12 shown in FIGS. 1 and 2. FIG. 4 illustrates a bottom view of the consolidated liquid heat exchanger 20 shown in FIG. 3. The consolidated liquid heat exchanger 20 comprises a body 21 having a liquid inlet port 22 and a liquid outlet port 23 that are coupled to an open cavity 24.

The consolidated liquid heat exchanger 20 is attached to the lid 13 of the CPU 10, or directly to the top of the CPU 10, using adhesive 25 (FIG. 6) disposed along a peripheral edge of the heat exchanger 20. No thermal interface material is used as is common when using conventional heat exchangers. Thermal interface material is required to reduce contact resistance between a conventional liquid heat exchanger and the object with which it exchanges heat, i.e., the microprocessors 12. The discussion in the Background section outlines the problems with this arrangement.

The consolidated liquid heat exchanger 20 is attached to the microprocessor 12 using the thermal adhesive 25. Consequently, the open cavity 24 allows cooling liquid to directly contact the microprocessors 12. An exemplary cooling liquid is dielectric fluid such Fluorinert, available from 3M, for example. The cooling liquid is pumped through the liquid inlet port 22, over the microprocessor 12, and out the liquid outlet port 23. This provides for improved cooling capability, particularly since there is no thermal interface material and there is no bottom cover used with the consolidated liquid heat exchanger 20, both of which are employed with conventional heat exchangers.

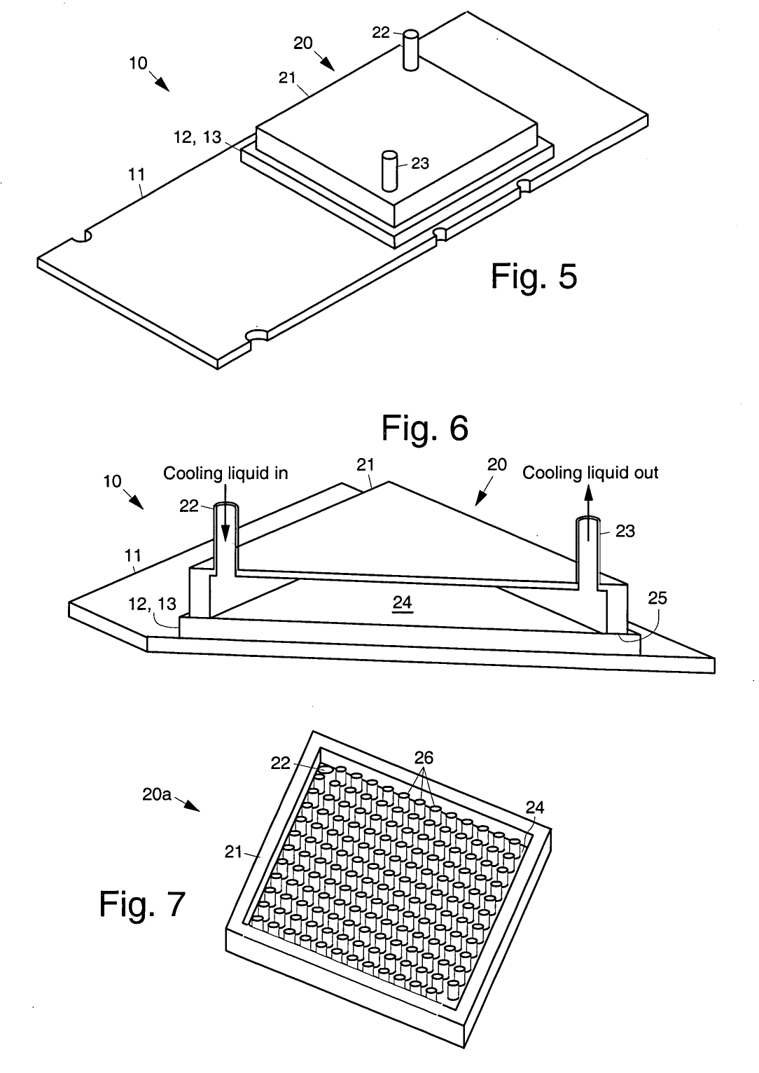

FIG. 5 illustrates a top view of the exemplary consolidated liquid heat exchanger 20 coupled to the microprocessor 12. FIG. 6 is a cutaway view of the consolidated liquid heat exchanger 20 shown in FIGS. 3-5. The liquid heat exchanger 20 is attached directly to the top of the microprocessor 12 along its periphery so that cooling liquid is free to contact the top surface of the microprocessor 12 as it flows through the cavity 24.

The use of the consolidated open cavity liquid heat exchanger 20 allows the liquid to directly contact the object with which heat is exchanged. By eliminating the bottom of the liquid heat exchanger 20 and hermetically bonding the liquid heat exchanger 2 to the object (microprocessor 12) with which heat is exchanged, the contact resistance and the resistance incurred by conducting into the liquid heat exchanger 20 are both eliminated.

The open design of the exemplary open liquid heat exchanger 20 allows the liquid to directly contact the object (microprocessor 20) with which the liquid heat exchanger 20 exchanges heat. The open liquid heat exchanger 10 is assembled directly to the object with which it exchanges heat, in this case the microprocessor 12 or CPU 12. The open liquid heat exchanger 20 is hermetically bonded to the object (microprocessor 20) with which it exchanges heat. This allows the cooling liquid to directly contact the microprocessor 12 without leaking. If required, additional mechanical mounting hardware may be used to ensure reliable attachment of the liquid heat exchanger 20 to the microprocessor 12.

Conventional computer systems have utilized a closed liquid heat exchanger. This requires the heat to flow through a contact resistance and through the bottom of the liquid heat exchanger. Each of these thermal resistances require a temperature difference to drive heat flow. For the specific case of a 130 Watt microprocessor 12, these two conductive resistances equate to a 19.8° C. temperature gradient (calculated using typical values for thermal interface material and a conventional copper liquid heat exchanger). The open cavity liquid heat exchanger 20 described herein eliminates both the above thermal resistances. This results in a 19.8° C. reduction in the temperature gradient for the corresponding structure using the open cavity liquid heat exchanger 20.

FIG. 7 illustrates a bottom view of an exemplary dual mode liquid heat exchanger 20a. The exemplary dual mode liquid heat exchanger 20a is similar to the consolidated liquid heat exchanger 20 discussed above, but it includes a plurality of heat-conducting pathways 26 comprising heat conducting fingers 26 or extended surfaces 26, extending inwardly from an inner bottom surface of the body 21 into the open cavity 24. The heat-conducting pathways 26 or fingers 26 extend into the cavity 24 a distance that allows them to contact the top surface of the microprocessor 12.

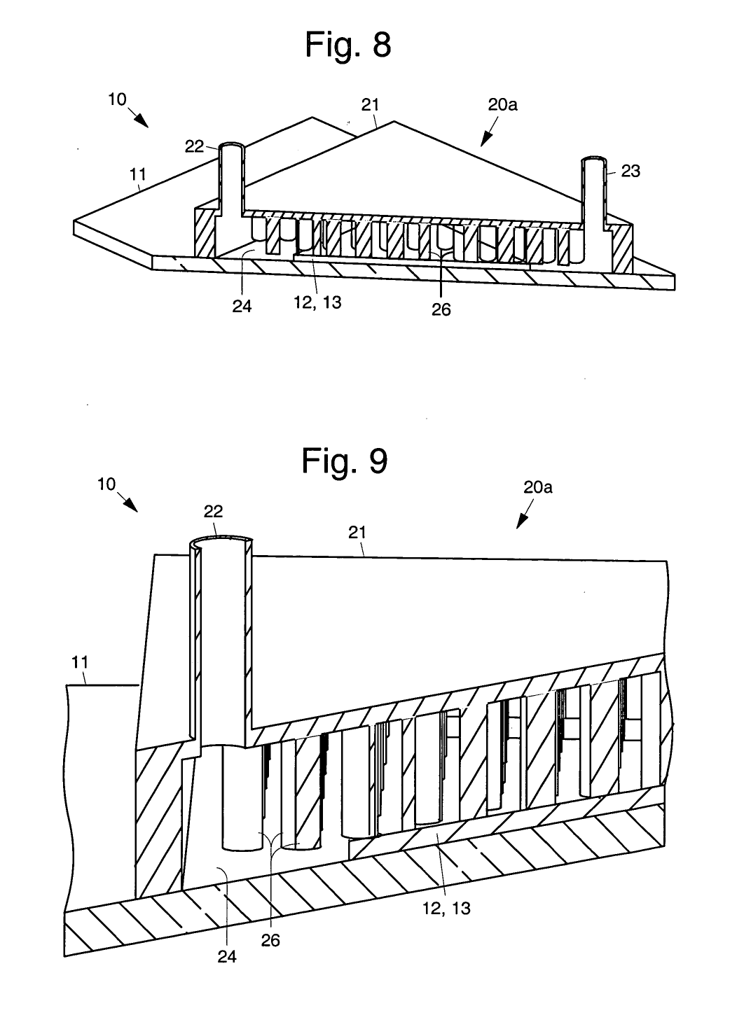

FIGS. 8 and 9 illustrate the exemplary dual mode heat transfer device 20a employed with a microprocessor 20. The exemplary dual mode heat transfer device 20a solves the problems discussed above in the Background section. This is achieved by providing heat-conducting pathways 26 between the top or lid of the microprocessor 20 and the body 21 of the heat transfer device 20a covering the microprocessor 20 in addition to liquid cooling channels between the pathways 26 within the cavity 24. The heat-conducting pathways 26 enhance the convective cooling performance of liquid 24 that flows through the channels of the cavity 24 while also giving the heat a low resistance path to the outer surface of the heat transfer device 20a. Therefore, the microprocessor 20 may be cooled by the liquid flowing through the heat transfer device 20a or air (external to the heat transfer device 20a) depending on customer preferences or failure of the liquid cooling system.

In another aspect, the dual mode heat transfer device 20a eliminates two conductive resistances by eliminating the bottom of the conventional liquid heat exchanger and mounting the heat transfer device 20a directly to the object (microprocessor 12) with which it exchanges heat. This also eliminates the need for thermal interface material.

The dual mode heat transfer device 20a incorporates the array of extended surfaces 26 or fingers 26 extending from the bottom surface of the body 21 of the heat transfer device 20a. These extended surfaces 26 directly contact (and may be bonded to) the microprocessor 12. These extended surfaces 24 or fingers 26 provide a very high conductivity pathway from the microprocessor 12 to the surface of the heat transfer device 20a. If a conventional heat sink is mounted to the surface of the heat transfer device 20a, heat may be effectively removed from the heat transfer device 20a and microprocessor 12.

It should be recognized that the conductive pathways 26 or fingers 26 are far superior to conduction through cooling fluid alone, and in the case of a liquid cooling system failure, these conductive pathways 26 are operative to prevent the microprocessor 20 from shutting down or overheating.

Additionally, utilization of liquid cooling is not expected to be adopted by all microprocessor customers simultaneously. Some customers may require it sooner than others. The dual mode heat transfer device 20a allows for a transition to liquid cooling. For customers who require it, they can obtain it. For customers who wish to continue using air cooling, the dual mode heat transfer device 20a will work for them as well. Furthermore, for those customers who wish to continue using air, the conductive performance of the dual mode heat transfer device 20a may be substantially improved by filling the volume of the cavity 24 that would be occupied by cooling liquid with a high conductivity thermal interface material, for example.

Advantages are that, in addition to liquid cooling, the dual mode liquid heat exchanger 20a allows heat to be conducted to the surface of the heat exchanger 20a where it may then be removed via a conventional air-cooled heat sink. The dual mode liquid heat exchanger 20a provides redundancy in the case of a liquid system failure. The dual mode liquid heat exchanger 20a may be operated in either a liquid cooling mode or a convective mode. The dual mode liquid heat exchanger 20a enhances the convective performance of the cooling liquid.

Thus, improved liquid heat exchangers and heat exchanging methods have been disclosed. It is to be understood that the above-described embodiments are merely illustrative of some of the many specific embodiments that represent applications of the principles described herein. Clearly, numerous and other arrangements can be readily devised by those skilled in the art without departing from the scope of the invention.

What is claimed is:

1. Apparatus, comprising:
a body having an open cavity whose periphery is sealable to an object from which heat is to be removed;
cooling liquid inlet and outlet ports coupled through the body to the open cavity;
wherein cooling liquid is free to flow into and through the cavity when sealed to the object, thereby contacting the object and removing heat from the central processing unit; and
a plurality of heat conducting elements extending from an inner surface of the body into the open cavity, at least some of which have a length that contact the object when the apparatus is sealed to the object, and wherein the heat conducting elements allow convective cooling of the object.

2. The apparatus recited in claim 1 wherein the object comprises a central processing unit and wherein some of the heat conducting elements have a length that is operative to contact the central processing unit when the apparatus is sealed to the central processing unit, and wherein the heat conducting elements allow convective cooling of the central processing unit.

3. The apparatus recited in claim 1 wherein the cooling liquid comprises dielectric fluid.

4. The apparatus recited in claim 2 wherein the body is hermetically bonded to the central processing unit.

5. The apparatus recited in claim 2 wherein the central processing unit comprises a microprocessor.

6. Heat exchanger apparatus for removing heat from a central processing unit, comprising:
a body having an open cavity whose periphery is sealable to the central processing unit from which heat is to be removed;
a cooling liquid inlet port coupled through the body to the open cavity;
a liquid outlet port coupled through the body to the open cavity; and
a plurality of heat conducting elements extending from an inner surface of the body into the open cavity, at least some of which have a length that is operative to contact the central processing unit when the apparatus is sealed to the central processing unit;
wherein cooling liquid is free to flow into and through the cavity when the body is sealed to the central processing unit, thereby contacting the object and removing heat from the central processing unit, and wherein the heat conducting elements allow convective cooling of the central processing unit.

7. The apparatus recited in claim 6 wherein the cooling liquid comprises dielectric fluid.

8. The apparatus recited in claim 6 wherein the body is hermetically bonded to the central processing unit.

9. The apparatus recited in claim 6 wherein the central processing unit comprises a microprocessor.

10. A method for removing heat from a central processing unit, comprising:
providing a liquid heat exchanger comprising a body with an open cavity whose periphery is sealable to the central processing unit from which heat is to be removed, a cooling liquid inlet port coupled through the body to the open cavity, a liquid outlet port coupled through the body to the open cavity, and a plurality of heat conducting elements extending from an inner surface of the body into the open cavity, at least some of which have a length that is operative to contact the central processing unit,.which heat conducting elements allow convective cooling of the central processing unit;
hermetically sealing the body to the central processing unit;
pumping cooling liquid through the liquid heat exchanger to cause cooling liquid to flow through the cavity and contact the central processing unit to remove heat therefrom.

11. The method recited in claim 10 wherein the cooling liquid comprises dielectric fluid.

12. The method recited in claim 10 wherein the central processing unit comprises a microprocessor.

13. The method recited in claim 10 wherein the cooling liquid comprises dielectric fluid.

14. The method recited in claim 10 wherein the central processing unit comprises a microprocessor.
